(19) United States
(12) Patent Application Publication
(10) Pub. No.: US 2015/0059832 A1
(43) Pub. Date: Mar. 5, 2015

(54) MANUFACTURE OF MULTIJUNCTION SOLAR CELL DEVICES

(71) Applicant: Soitec, Crolles Cedex (FR)

(72) Inventors: Bruno Ghyselen, Seyssinet (FR); Chantal Arena, Mesa, AZ (US); Frank Dimroth, Freiburg (DE); Matthias Grave, Freiburg (DE)

(73) Assignee: SOITEC, Crolles Cedex (FR)

(21) Appl. No.: 14/387,662

(22) PCT Filed: Mar. 13, 2013
(86) PCT No.: PCT/EP2013/055134

§ 371 Date: Sep. 24, 2014

(30) Foreign Application Priority Data
Mar. 28, 2012 (EP) 12290109.3

(51) Int. Cl. H01L 31/0725; H01L 31/0735; H01L 31/18

(52) U.S. Cl. CPC H01L 31/0725; H01L 31/1844; H01L 31/1852; H01L 31/0735; H01L 31/1892
USPC 136/249; 438/94

(57) ABSTRACT

The present disclosure relates to a method for manufacturing a multi-junction solar cell device comprising the steps of: providing a final base substrate; providing a first engineered substrate comprising a first zipper layer and a first seed layer; providing a second substrate; transferring the first seed layer to the final base substrate; forming at least one first solar cell layer on the first seed layer after transferring the first seed layer to the final base substrate, thereby obtaining a first wafer structure; forming at least one second solar cell layer on the second substrate, thereby obtaining a second wafer structure; and bonding the first and the second wafer structure to each other.

### CROSS-REFERENCE TO RELATED APPLICATIONS

This application is a national phase entry under 35 U.S.C. §371 of International Patent Application PCT/EP2013/055134, filed Mar. 13, 2013, designating the United States of America and published in English as International Patent Publication WO 2013/143851 A1 on Oct. 3, 2013, which claims the benefit under Article 8 of the Patent Cooperation Treaty and under 35 U.S.C. §119(e) to European Patent Application Serial No. 12290109.3, filed Mar. 28, 2012, the disclosure of each of which is hereby incorporated herein in its entirety by this reference.

### TECHNICAL FIELD

The present disclosure relates to the manufacture of multi-junction solar cell substrates, in particular, to the manufacture of multi-junction solar cell substrates comprising wafer transfer processes and the manufacture of solar cell devices for terrestrial and space-related applications.

### BACKGROUND

Photovoltaic or solar cells are designed for converting the solar radiation to electrical current. In concentrator solar photovoltaic applications, the incoming sunlight is optically concentrated before it is directed to solar cells. For example, the incoming sunlight is received by a primary mirror that reflects the received radiation toward a secondary mirror that, in turn, reflects the radiation toward a solar cell, which converts the concentrated radiation to electrical current by the generation of electron-hole pairs in III-V semiconductor or single crystal silicon, for example. Alternatively, the sunlight could be concentrated onto solar cells by using transmittive optics like Fresnel lenses.

Since different semiconductor material composition show optimal absorption for different wavelengths of the incoming solar light, multi-junction solar cells have been proposed that comprise, for example, three cells showing optimal absorption in different wavelength ranges. A triple cell structure may comprise, for example, a GaInP top cell layer with a gap value of 1.8 eV, a GaAs intermediate cell layer with a gap value of 1.4 eV, and a Ge bottom cell layer with a gap value of 0.7 eV. In principle, III-V or IV semiconductors can be used as active subcells of multi-junction cell devices manufactured by layer transfer/bonding. Multi-junction solar cells are usually manufactured by monolithic epitaxial growth. The monolithic growth process requires, in general, that any formed layers be substantially lattice matched to previously formed layers or the underlying substrate. However, the epitaxial growth of the solar cell layers on growth substrates still provides a demanding problem in view of lattice mismatches. For example, it is not suitable to epitaxially grow an InP solar cell layer on a Ge substrate, since the crystalline and optical characteristics of the InP solar cell layer would be heavily deteriorated due to crystal mismatch. In addition, in conventionally used transfer processes, intermediate substrates are lost after the transfer of epitaxially grown layers.

Thus, despite the recent engineering progress, there is still a need for an improved manufacturing process for multi junction solar cell devices.

### BRIEF SUMMARY

The present disclosure addresses the above-mentioned need and, accordingly, provides a method for manufacturing a multi-junction solar cell device, comprising the steps of
providing a final base substrate;
providing a second substrate;
transferring a first seed layer to the final base substrate;
forming at least one first solar cell layer on the first seed layer after transferring the first seed layer to the final base substrate, thereby obtaining a first wafer structure;
forming at least one second solar cell layer on the second substrate, thereby obtaining a second wafer structure; and
bonding the at least one second solar cell to the first wafer structure.

By the term “final base substrate,” it is indicated that this base substrate will be the base substrate of the eventually completely manufactured multi-junction solar cell.

The step of bonding the at least one second solar cell to the first wafer structure comprises bonding the at least one second solar cell layer to the at least one first solar cell layer. A configuration with stacked solar cell layers can be obtained with a relatively small number of transfer steps, thereby reducing the complexity of the manufacture of multi-junction solar cells, as compared to the manufacturing process of the art.

The term “engineered substrate” comprises a substrate that is different from a mere pure bulk substrate, but rather includes a layer or interface that is formed in the substrate in order to facilitate its partial removal. In particular, the “engineered substrate” may comprise a zipper layer between a seed layer and a base substrate. In particular, the engineered substrate may comprise a base substrate that is detached from the seed layer in the step of removal of the engineered substrate.

Detachment by means of the zipper layer allows for recycling the detached substrate.

In the document, the expression “detachment of the engineered substrate” should be interpreted as the detachment of the base substrate. This detachment step may be followed by the removal of the possible residue of the zipper layer (if any), and of the removal of the seed layer from the remaining structure.

The zipper layer may be a weakened layer formed, e.g., by an appropriate treatment, for instance, a hydrogen or helium implantation in a substrate, that delimits an upper seed layer and a lower base substrate.

The zipper layer may be formed by a buried porous layer by anodic etching at a surface of the base substrate. Then, epitaxial growth of the seed layer can be performed on top of the porous layer.

The zipper layer may be provided in form of an absorbing layer for laser lift-off, chemical lift-off or mechanical splitting in an intermediate strained layer during an epitaxy sequence: SiGe in Si matrix, in particular, an intermediate strained layer of SiGe at 20% in an Si substrate. In this alternative, the zipper layer may be formed by the seed layer itself; for instance, the seed layer can be selectively and chemically etched away to detach the engineered substrate.

The zipper layer may also be formed of an SiN absorbing layer for laser lift-off inserted between a seed layer and a transparent base substrate, as known, for example, from WO2010/015878.

Another possibility for an engineered substrate reads as follows: A removable (presenting a low bonding energy of less than 1.5 J/m², and preferentially less than 1 J/m²) bonding interface is formed between facing surfaces of a seed layer and a base support. In that possibility, the zipper layer is formed by the removable bonding interface. A first solar cell layer may be grown by epitaxy on the seed layer while preserving the removable character of the bonding interface, with the engineered substrate being heated to an epitaxial growth temperature. The low energy bonding is obtained by performing a treatment for augmenting the roughness of the facing surface of one of the seed layer or the substrate, in particular, carried out by chemical attack or etching, by effecting a treatment for decreasing hydrophilicity of the facing surface of one of the seed layer or the substrate (or the bonding layer in SiO₂ or Si₃N₄ on each of them). Moreover, a different material for the bonding layer can be chosen, such that weak intrinsic mutual chemical affinity of the interface materials is achieved. The detachment of the base substrate may be performed by application of a thermal treatment or mechanical stresses applied from a jet of fluid or a blade, for example. This is disclosed, for instance, in WO03/063214.

As already mentioned, the engineered substrate includes a seed layer foamed at the top of the zipper layer or removable bonding interface. The seed layer is transferred from the seed substrate to a base substrate by layer transfer from wafer to wafer, for example, by the SMARTCUT® process. The seed layer may or may not contain an epitaxial layer that has been formed originally by epitaxy on the seed substrate. Alternatively, the seed layer has been transferred or detached from a bulk seed substrate. In a preferred embodiment of the present disclosure, the seed layer is not used as a solar cell layer, but rather a first solar cell layer is grown on the seed layer.

The first seed layer may be exfoliated from an InP bulk substrate by H or He implants in some implantation layer. A part of the InP bulk substrate can then be detached after bonding to the final base substrate, such that only a thin InP layer is formed on the final base substrate. A solar cell layer can be grown on the InP layer with high crystal and electrical quality. For example, a dislocation density of less than 10⁶/cm² can be achieved.

A final base substrate made of tungsten or molybdenum or doped semiconductors like Ge, GaAs or InP may be particularly suitable for receiving the stack of solar cell layers provided on a second substrate made of, for instance, GaAs or GaAsOS (see below). In particular, the difference in CTE of the final base substrate to the CTE of the second substrate should be less than 30% in order to avoid problems related to the bonding to the final substrate. Similar substrates allow higher bonding temperatures due the perfect matching in CTE. Further the final base substrate has to be electrically conductive. In order to avoid metallic contamination, the choice of doped semiconductors, in particular, GaAs, may be particularly advantageous.

The second substrate can be provided in the form of an engineered substrate, in particular, comprising a sapphire base and a GaAs or Ge seed layer. After bonding to the at least one first solar cell layer formed on the final base substrate or on a handling substrate (as it will be described below), the bulk sapphire can be detached at a zipper layer.

Alternatively, the second substrate can be made of, or comprise, a massive material like, for instance, GaAs or Ge. Grinding and/or etching of the second substrate may then be performed, after bonding, to obtain a free main surface of the at least one second solar cell layer.

According to a particular variant, in the above-described examples, the at least one first solar cell layer comprises two layers, a first layer and a second layer that has been formed, in particular, grown by epitaxy, on the first layer, and the at least one second solar cell layer also comprises two layers, namely, a third layer and a fourth layer that has been foamed, in particular, grown by epitaxy, on the third layer.

Preferably, in this variant, the method further comprises the steps of:
attaching a handling substrate to the second wafer structure at the at least second solar cell layer;
removing and, in particular, detaching the second substrate to obtain a third wafer structure; and
bonding the third wafer structure to the first wafer structure.

According to a particular example of this variant, the first solar cell layer comprises a first layer and a second layer and the second solar cell layer comprises a third layer and a fourth layer. In this case, the first layer (bottom cell) comprises or consists of GaInAs, and/or the second layer comprises or consists of GaInAsP, and/or the fourth layer (top cell in the finished multi junction solar cell device) comprises or consists of GaInP, and/or the third layer comprises or consists of GaAs. Thus, a four-cell multi-junction solar cell device is achieved wherein the material of each cell is optimized for a particular wavelength of the incoming solar light. By the use of the intermediate handling substrate, no inversion of layers is necessary during the entire manufacturing process according to this embodiment (i.e., the layer having a larger band gap is grown on top of the layer that has a smaller band gap).

As already mentioned, the at least one second solar cell layer is formed on the at least one first solar cell layer by direct bonding.

According to another variant, the first solar cell layer comprises a first layer and a second layer and the second solar cell layer comprises a fourth layer and a third layer. The sequence of enumeration of the third and fourth layers is reversed as compared to the previously described alternative. The third layer is formed on the fourth layer formed on the second substrate. Then, the third layer is bonded to the second layer formed on the first layer formed on the first seed layer. Thereby, inversion of layers (namely the third and fourth layers) during their formation on the second substrate is required (i.e., the layer having a smaller band gap is grown on top of the layer that has a wider band gap), but the integration process does not necessitate an intermediate handling substrate.

According to a particular example of this variant, the first layer (bottom cell) comprises or consists of GaInAs, and/or the second layer comprises or consists of GaInAsP, and/or the fourth layer (top cell in the finished multi junction solar cell device) comprises or consists of GaInP, and/or the third layer comprises or consists of GaAs (see also detailed description below).

The present disclosure also provides a multi junction solar cell device, consisting of:
a final base substrate made of Mo, W, Ge, GaAs or InP;
a seed layer, in particular, an InP seed layer formed, in particular, bonded, on the final base substrate; and
at least one first solar cell layer and at least one second solar cell layer formed on the seed layer.

In addition, a multi-junction solar cell device is provided that is obtainable by one of the above-described examples of the method for the manufacture of a multi-junction solar cell device according to the present disclosure.

### BRIEF DESCRIPTION OF THE DRAWINGS

Additional features and advantages of the present disclosure will be described with reference to the drawings. In the description, reference is made to the accompanying figures that are meant to illustrate embodiments of the disclosure. It is understood that such embodiments do not represent the full scope of the disclosure.

FIG. 1 illustrates an example for the inventive method for the manufacturing of a multi-junction solar cell employing inversion of solar cell layers.

FIG. 2 illustrates an example for the inventive method for the manufacturing of a multi-junction solar cell without the inversion of solar cell layers.

### DETAILED DESCRIPTION

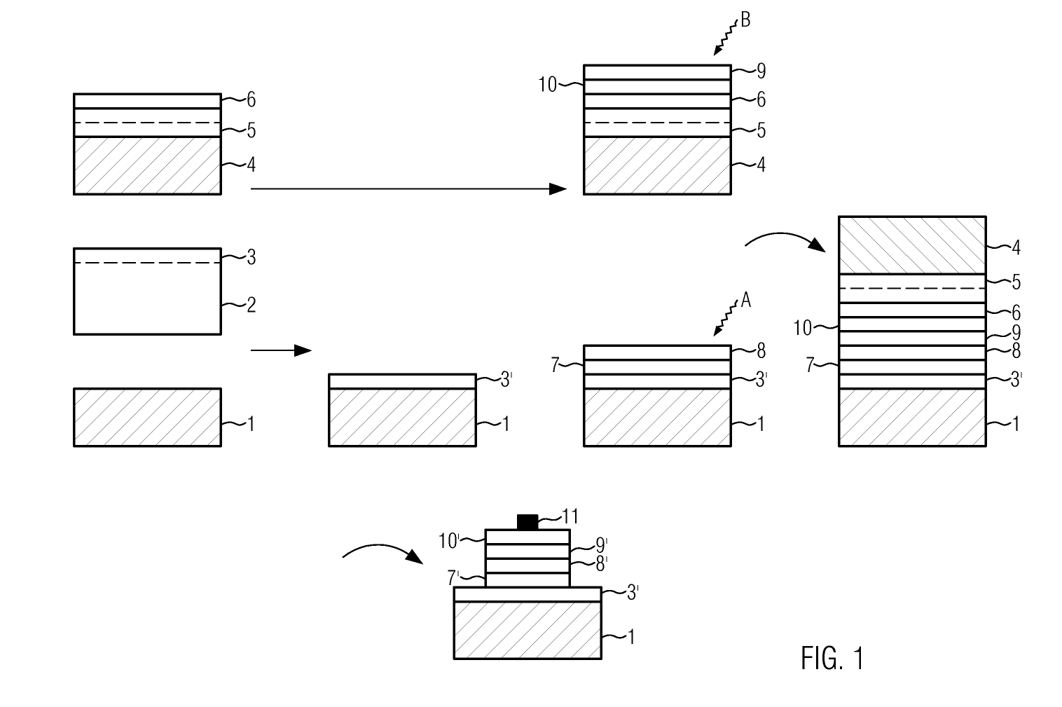

An example for the disclosed method for the manufacturing of a multi-junction solar cell comprising four solar cell layers is shown in FIG. 1. A final base substrate 1 is provided. The final base substrate 1 may be made of Mo, W, Ge, GaAs or InP. The final base substrate 1 will be the base substrate of the completed multi-junction solar cell and provides mechanical stability during the processing and, preferably, thermal, electrical conductivity during operation of the solar cell. A first substrate 2 comprising an implantation layer 3 (weakened layer) for later detachment of the first substrate 2 is provided. For example, the first substrate 2 is an InP bulk substrate. Implants for forming the implantation layer can comprise H and/or He.

A final base substrate made of tungsten or molybdenum or doped semiconductors like Ge, GaAs or InP may be particularly suitable for receiving the stack of solar cell layers provided on a second substrate made of, for example, GaAs or GaAsOS (see below). In particular, the difference in CTE of the final base substrate to the CTE of the second substrate should be less than 30% in order to avoid problems related to the bonding to the final substrate. Similar substrates allow higher bonding temperatures due to the perfect matching in CTE. Further, the final base substrate has to be electrically conductive. In order to avoid metallic contamination, the choice of doped semiconductors, in particular GaAs, may be particularly advantageous.

The first substrate 2 is bonded to the final base substrate 1. After bonding, the main part of the first substrate 2 is detached by means of the implantation layer 3 as it is known in the art. For example, the SMARTCUT® process may be employed. The detached bulk InP can be recycled. The thickness of the resulting InP layer 3′ fainted on the final base substrate 1 may be in the range of 50 nm to 1 μm. The free (upper) surface of the InP layer 3′ may be prepared by polishing, etching, etc.

Alternatively, the seed layer can be formed on the final base substrate by bonding the first substrate on the final base substrate and reducing the thickness of the first substrate, for example, by grinding, etching.

Furthermore, an engineered substrate is provided comprising a sapphire base 4, a zipper layer 5 and a GaAs or Ge (seed) layer 6. Sapphire may preferably be chosen in view of its coefficient of thermal expansion, which is of importance for the temperature change (up and down) during epitaxy and for the further processing, in particular, bonding step (see below). Moreover, sapphire is transparent to laser light and can, thus, allow for laser lift-off in a later processing step (see below). The zipper layer 5 may be provided in the form of an absorbing layer for laser lift-off.

Subsequently, a first solar cell layer 7 and a second solar cell layer 8 are formed on the free surface of the InP layer 3′, resulting in a first wafer structure A. Similarly, a fourth solar cell layer 10 and a third solar cell layer 9 are formed on the GaAs or Ge layer 6 of the engineered substrate, resulting in a second wafer structure B.

The four solar cell layers 7-10 show absorption maxima for incident solar light for different wavelengths. The first solar cell layer 7 becomes the bottom cell and the fourth solar cell layer 10 becomes the top cell in the finished multi junction solar cell device. According to the present example, all of the four monocrystal solar cell layers 7-10 are formed by epitaxial growth. In principle, the material of the solar cell layers can be selected form III-V semiconductors of the group consisting of InGaAs, GaAS, AlGaAs, InGaP, InP and InGaAsP. For example, the first solar cell layer 7 may be comprised of InGaAs, the second solar cell layer 8 may be comprised of InGaP, InGaAsP or InP, the third solar cell layer 9 may be comprised of GaAsP or GaAs, and the fourth solar cell layer 10 may be comprised of InGaP or InAlAs. Appropriate tunnel junction layers may be provided between particular ones of the solar cell layers by deposition or growth on a respective solar cell layer.

In the next step illustrated in FIG. 1, the first wafer structure A and the second wafer structure B are bonded to each other. In case of direct bonding, which forms the preferred embodiment according to the disclosure, the polishing of the surface of the solar cell layers to be bonded may be performed in order to smooth the surface, better than to 0.5 nm RMS over a field of 5×5 micrometers, for example, to obtain an enhanced bonding strength between the solar cell layers and improved efficiency and reliability of the subsequent solar cell. Alternatively, an electrically conductive, optically transparent material can be used as a bonding layer and facilitates the adhesion of the two structures. In any case, the bonding interface is between the second solar cell layer 8 and the third solar cell layer 9. The sapphire base 4 of the second engineered substrate is then detached by means of the zipper layer 5 and the GaAs or Ge layer 6 is removed, for instance, by etching, thereby resulting in a free upper main surface of the fourth solar cell layer 10. Detachment by means of the zipper layer allows for recycling the detached sapphire base 4.

It should be noted that relatively high temperatures may be involved in the step of bonding the first wafer structure A and the second wafer structure B to each other. Contacting and bonding can be performed at relatively high temperatures of about 400° C. to 600° C. and, more preferably, between 450° C. and 550° C. Preferably, the contacting step is performed at room temperature followed by an annealing step reaching max temperature between 400° C. and 600° C., although it is not excluded to perform the contacting step at a higher temperature. This bonding step is crucial for the quality of the resulting multi-junction solar cell and it is favorable to perform a high-temperature bonding anneal in order to achieve a high-quality bonding interface between the lower surface of the second substrate and the second solar cell layer 5 without significant defects.

The material for the final base substrate 1 may be chosen according to the coefficient of thermal expansion of the various materials involved during bonding. It is Mo that may preferably be chosen in this respect, in particular, if the engineered substrate comprises a sapphire base.

A final base substrate made of tungsten or molybdenum or doped semiconductors like Ge, GaAs or InP may be particularly suitable for receiving the stack of solar cell layers provided on a second substrate made of for example, GaAs or GaAsOS (see below). In particular, the difference in CTE of the final base substrate to the CTE of the second substrate should be less than 30% in order to avoid problems related to the bonding to the final substrate.

The resulting structure is subject to some finish processing comprising the formation of a plurality of mesas comprising etched solar cell layers 7′, 8′, 9′ and 10′. The formation of the mesas can be achieved by lithographic processing after the formation of an appropriately patterned photoresist and optionally formed anti-reflective coating. An electrical contact 11 is formed on the patterned fourth solar cell layer 10′.

It should be noted that instead of the engineered substrate, a GaAs or Ge bulk substrate can be used as the second substrate. The second substrate is then removed by etching/grinding after bonding of the first wafer structure A.

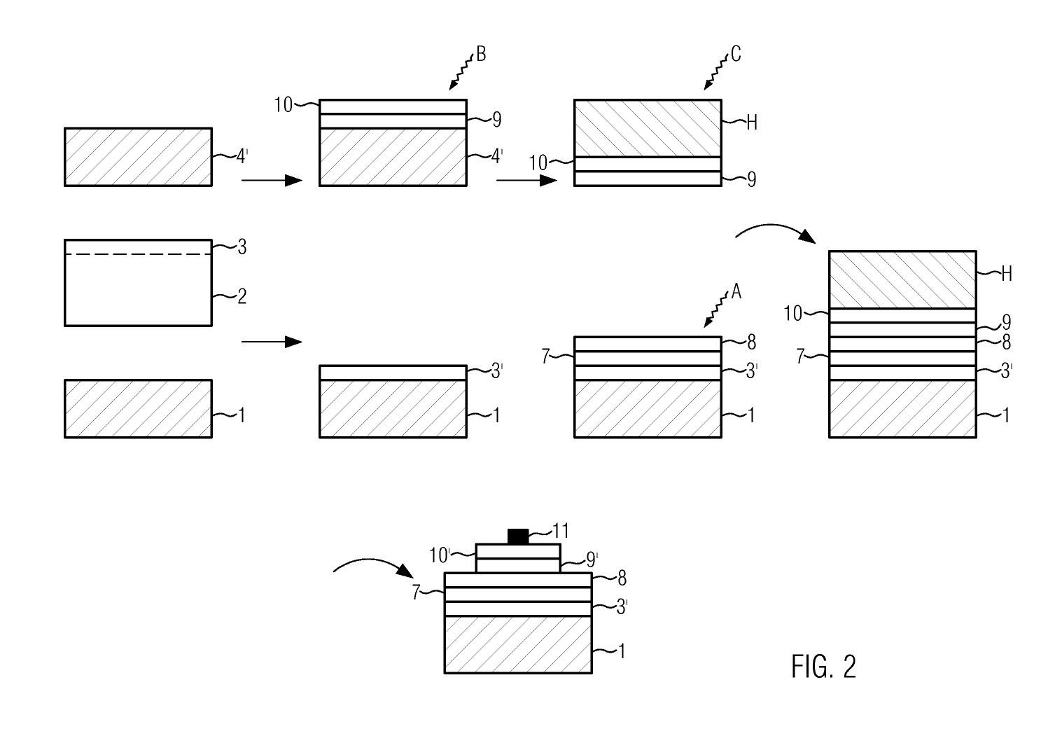

FIG. 2 illustrates another example for the herein-disclosed method. According to the example shown in FIG. 1, inversion of third and fourth solar cell layers 9 and 10 on the second substrate is necessary. To the contrary, in the example illustrated in FIG. 2, no such inversion is included in the manufacturing process.

As in the example of FIG. 1, a final base substrate 1 is provided. The final base substrate 1 may be made of Mo, W, Ge, GaAs or InP. A first substrate 2 comprising an implantation layer (weakened layer) 3 for later detachment of the first substrate 2 is provided. For example, the first substrate 2 is an InP bulk substrate comprising a weakened layer 3. A second substrate 4′ is provided in the faun of a GaAs or Ge bulk substrate. A thin InP 3′ is transferred from the first substrate 2 to the final base substrate 1 as it is described in the example shown in FIG. 1. Moreover, a first solar cell layer 7 and a second solar cell layer 8 are formed on the InP layer 3′, resulting in a first wafer structure A. Similarly, a third solar cell layer 9 and a fourth solar cell layer 10 are formed on the GaAs or Ge bulk substrate 4′. For the first solar cell layer 7 to the fourth solar cell layer 10, the same materials can be chosen as in the example illustrated in FIG. 1.

Then, a handling substrate H is attached by means of an adhesive layer to the fourth solar cell layer 10. The handling substrate can be a glass substrate, and the adhesive can be a glue layer. Then the second substrate 4′ can be removed to form the structure C. In the case where the second substrate is an engineered substrate, it can be detached.

Bonding of the first and second wafer structures A and C results in the configuration shown on the right-hand side of the upper row of FIG. 2. Contacting and bonding can be performed as described in the previous example. The handling wafer H is removed after bonding.

The resulting structure is subject to some finish processing comprising the formation of a plurality of mesas comprising etched solar cell layers 9′ and 10′. The formation of the mesas can be achieved by lithographic processing after the formation of an appropriately patterned photoresist and optionally formed anti-reflective coating. An electrical contact 11 is formed on the patterned fourth solar cell layer 10′.

All previously discussed embodiments are not intended as limitations but serve as examples illustrating features and advantages of this disclosure. It has to be understood that some or all of the above-described features can also be combined in different ways. In particular, it is possible according to the disclosure to form multi-junction solar cells not only composed of four junctions (as generally disclosed in the previous embodiments) but also 2, 3, 5 or more.

1. A method for manufacturing a multi-junction solar cell device comprising the steps of:
providing a final base substrate;
providing a second substrate;
transferring a first seed layer to the final base substrate;
forming at least one first solar cell layer on the first seed layer after transferring the first seed layer to the final base substrate, thereby obtaining a first wafer structure;
forming at least one second solar cell layer on the second substrate, thereby obtaining a second wafer structure; and
bonding the at least one second solar cell to the first wafer structure.

2. The method according to claim 1, wherein the step of bonding the at least one second solar cell to the first wafer structure comprises bonding the at least one second solar cell layer with the second substrate thereon to the at least one first solar cell layer.

3. The method according to claim 1, wherein the step of bonding the at least one second solar cell to the first wafer structure comprises directly bonding the at least one second solar cell layer to the at least one first solar cell layer.

4. The method according to claim 1, wherein the step of transferring the first seed layer to the final base substrate comprises a step of bonding a first substrate to the final base substrate and detaching a part of the first substrate at an implantation layer.

5. The method according to claim 1, further comprising forming a second seed layer on the second substrate and subsequently foaming the at least one second solar cell layer on the second seed layer.

6. The method according to claim 1, further comprising bonding the second wafer structure to a handling substrate, removing the second substrate, and wherein the step of bonding the at least one second solar cell layer to the first wafer structure comprises bonding the at least one second solar cell layer with the handling substrate thereon to the at least one first solar cell layer.

7. The method according to claim 1, wherein the second substrate is a GaAS or Ge bulk substrate, or an engineered substrate comprising a zipper layer, a sapphire base and a GaAs or Ge seed layer.

8. The method according to claim 7, wherein the second substrate is the engineered substrate, and further comprising detaching the sapphire base of the second engineered substrate after bonding the at least one second solar cell to the first wafer structure.

9. The method according to claim 1, wherein the at least one first solar cell layer comprises a first layer and a second layer on the first layer and/or the at least one second solar cell layer comprises a third layer and a fourth layer on the third layer.

10. The method according to claim 2, wherein the at least one first solar cell layer comprises a first layer and a second layer on the first layer, and/or the at least one second solar cell layer comprises a third layer and a fourth layer on the third layer, and wherein the first layer comprises GaInAs, and/or the second layer comprises GaInAsP, and/or the third layer comprises or consists of GaAs, and/or the fourth layer comprises GaInP.

11. The method according to claim 3, wherein the at least one first solar cell layer comprises a first layer and a second layer on the first layer, and/or the at least one second solar cell layer comprises a fourth layer and a third layer on the fourth layer, and wherein the first layer comprises GaInAs, and/or the second layer comprises GaInAsP, and/or the third layer comprises GaAs, and/or the fourth layer comprises GaInP.

12. The method according to claim 1, wherein the final base substrate comprises at least one of Mo, W, Ge, GaAs Of and InP.

13. The method according to claim 1, further comprising:
forming mesas of the at least one first solar cell layer and the at least one second solar cell layer; and
forming a contact on a free main surface of the at least one second solar cell layer.

14. A multi-junction solar cell device fabricated by a method comprising the steps of:
providing a final base substrate;
providing a second substrate;
transferring a first seed layer to the final base substrate;
forming at least one first solar cell layer on the first seed layer after transferring the first seed layer to the final base substrate, thereby obtaining a first wafer structure;
forming at least one second solar cell layer on the second substrate, thereby obtaining a second wafer structure; and
bonding the at least one second solar cell to the first wafer structure.

15. A multi-junction solar cell, comprising:
a final base substrate comprising one of Mo, W, Ge, GaAs and InP;
an InP seed layer bonded to the final base substrate; and
at least one first solar cell layer and at least one second solar cell layer disposed on the seed layer.

16. The multi-junction solar cell of claim 15, wherein the at least one second solar cell layer is bonded onto the at least one first solar cell layer.
